(19) United States
(12) Patent Application Publication
(10) Pub. No.: US 2010/0129616 A1
(43) Pub. Date: May 27, 2010

(54) NEGATIVE-WORKING ON-PRESS DEVELOPABLE IMAGEABLE ELEMENTS

(76) Inventors: Jeffrey J. Collins, Greeley, CO (US); Kevin B. Ray, Hudson, NH (US); Kevin D. Wieland, Greeley, CO (US)

Correspondence Address: J. Lanny Tucker;Patent Legal Staff, Eastman Kodak Company, 343 State Street, Rochester, NY, 14650-2201, US

(21) Appl. No.: 12/275,262

(22) Filed: Nov. 21, 2008

(51) Int. Cl. G03F 7/20; G03F 7/029

(52) U.S. Cl. 428/195.1; 430/287.1; 430/302

(57) ABSTRACT

Negative-working imageable elements can be imaged and processed on-press to provide lithographic printing plates, especially with sulfuric acid-anodized aluminum substrates. These elements have an imageable layer that contains two different polymeric binders, a first polymeric binder that is present a discrete particles, and a second polymeric binder that comprises pendant ethylenically unsaturated groups.

### FIELD OF THE INVENTION

This invention relates to negative-working imageable elements such as negative-working lithographic printing plate precursors containing a unique combination of polymeric binders in the imageable layer. These imageable elements can be developed on-press after imaging. The invention also relates to a method of using these imageable elements.

### BACKGROUND OF THE INVENTION

Radiation-sensitive compositions are routinely used in the preparation of imageable materials including lithographic printing plate precursors. Such compositions generally include a radiation-sensitive component, an initiator system, and a binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and unexposed regions are washed off during development. For positive-working printing plates, the exposed regions are dissolved in a developer and the unexposed regions become an image.

Various negative-working radiation compositions and imageable elements containing polymer binders are known in the art. Some of these compositions and elements are described for example in U.S. Pat. No. 6,569,603 (Furukawa), U.S. Pat. No. 6,309,792 (Hauck et al.), U.S. Pat. No. 6,582,882 (Pappas et al.), U.S. Pat. No. 6,787,281 (Tao et al.), U.S. Pat. No. 6,893,797 (Munnelly et al.), U.S. Pat. No. 7,175,969 (Ray et al.), U.S. Pat. No. 7,172,850 (Munnelly et al.), U.S. Pat. No. 7,332,253 (Tao et al.), U.S. Pat. No. 7,326,521 (Tao et al.), U.S. Patent Application Publications 2003/0118939 (West et al.), 2005/0003285 (Hayashi et al.), 2005/0008971 (Mitsumoto et al.), 2005/0204943 (Makino et al.), and 2007/0184380 (Tao et al.), and EP Publications 1,079,276A1 (Lifka et al.), EP 1,182,033A (Fujimaki et al.), and EP 1,449,650A1 (Goto).

Various negative-working imageable elements have been designed for processing or development “on-press” using a fountain solution, lithographic printing ink, or both. For example, such elements are described in U.S. Patent Application Publication 2005-263021 (Mitsumoto et al.) and in U.S. Pat. No. 6,071,675 (Teng), U.S. Pat. No. 6,387,595 (Teng), U.S. Pat. No. 6,482,571 (Teng), U.S. Pat. No. 6,495,310 (Teng), U.S. Pat. No. 6,541,183 (Teng), U.S. Pat. No. 6,548,222 (Teng), U.S. Pat. No. 6,576,401 (Teng), U.S. Pat. No. 6,899,994 (Huang et al.), U.S. Pat. No. 6,902,866 (Teng), and U.S. Pat. No. 7,089,856 (Teng).

U.S. Pat. No. 7,300,740 (Yamasaki et al.) describes imageable elements containing polymeric binders having ethylenically unsaturated side chains.

### SUMMARY OF THE INVENTION

This invention provides a negative-working, on-press developable imageable element comprising a substrate having thereon an imageable layer and a topcoat as the outermost layer, the imageable layer comprising:

a free radically polymerizable component,

an initiator composition capable of generating radicals sufficient to initiate polymerization of the free radically polymerizable component upon exposure to imaging radiation,

an infrared radiation absorbing compound,

a first polymeric binder that is present as discrete particles distributed throughout the imageable layer, and

a second polymeric binder that comprises a hydrophobic backbone and pendant ethylenically unsaturated groups.

This invention also provides a method of making an imaged element comprising:

A) imagewise exposing the negative-working, on-press developable imageable element of this invention to form exposed and non-exposed regions,

B) with or without a preheat step, developing the imagewise exposed element to remove predominantly only the non-exposed regions.

For example, the method of this invention can be used to provide imaged lithographic printing plates especially having sulfuric acid-anodized aluminum-containing substrates.

Applicants have discovered a need to improve imageable elements especially when they have an imageable layer disposed on a sulfuric acid-anodized aluminum substrate. They have found a way to reduce on-press variability in developability. The present invention provides highly sensitive on-press developable, negative-working imageable elements that provide good run length and consistency in developability no matter the type of aluminum-containing substrate that is used. In addition, a preheat step between imaging and on-press development can be avoided if desired.

### DETAILED DESCRIPTION OF THE INVENTION

### Definitions

Unless the context indicates otherwise, when used herein, the terms “imageable element”, “lithographic printing plate precursor”, and “printing plate precursor” are meant to be references to embodiments of the present invention.

In addition, unless the context indicates otherwise, the various components described herein such as “first polymeric binder”, “second polymeric binder”, “free radically polymerizable component”, “infrared radiation absorbing compound”, “phosphate (meth)acrylate”, and similar terms also refer to mixtures of such components. Thus, the use of the articles “a”, “an”, and “the” is not necessarily meant to refer to only a single component.

Moreover, unless otherwise indicated, percentages refer to percents by dry weight.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of at least 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imageable Layers

The imageable elements include an infrared (IR) radiation-sensitive composition disposed on a suitable substrate to form an imageable layer. The imageable elements may have any utility wherever there is a need for an applied coating that is polymerizable using suitable radiation, and particularly where it is desired to remove non-exposed regions of the coating instead of exposed regions. The IR radiation-sensitive compositions can be used to prepare an imageable layer in imageable elements such as printed circuit boards for integrated circuits, microoptical devices, color filters, photomasks, and printed forms such as lithographic printing plate precursors that are defined in more detail below.

The IR radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated components that can be polymerized or crosslinked include ethylenically unsaturated polymerizable monomers that have one or more of the polymerizable groups, including unsaturated esters of alcohols, such as acrylate and methacrylate esters of polyols. Oligomers or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.).

Other useful free radically polymerizable components include those described in copending and commonly assigned U.S. Ser. No. 11/949,810 (filed Dec. 4, 2007 by Bauman, Dwars, Strehmel, Simpson, Savariar-Hauck, and Hauck) that include 1H-tetrazole groups. This copending application is incorporated herein by reference.

In addition to, or in place of the free radically polymerizable components described above, the IR radiation-sensitive composition may include polymeric materials that include side chains attached to the backbone, which side chains include one or more free radically polymerizable groups (such as ethylenically unsaturated groups) that can be polymerized (crosslinked) in response to free radicals produced by the initiator composition (described below). There may be at least two of these side chains per molecule. The free radically polymerizable groups (or ethylenically unsaturated groups) can be part of aliphatic or aromatic acrylate side chains attached to the polymeric backbone. Generally, there are at least 2 and up to 20 such groups per molecule, or typically from 2 to 10 such groups per molecule.

Such free radically polymerizable polymers can also comprise hydrophilic groups including but not limited to, carboxy, sulfo, or phospho groups, either attached directly to the backbone or attached as part of side chains other than the free radically polymerizable side chains.

Useful commercial products that comprise polymers that can be used in this manner include Bayhydrol® UV VP LS 2280, Bayhydrol® UV VP LS 2282, Bayhydrol® UV VP LS 2317, Bayhydrol® UV VP LS 2348, and Bayhydrol® UV XP 2420, that are all available from Bayer MaterialScience, as well as Laromer™ LR 8949, Laromer LR 8983, and Laromer™ LR 9005, that are all available from BASF.

The one or more free radically polymerizable components (monomeric, oligomeric, or polymeric) can be present in the imageable layer in an amount of at least 10 weight % and up to 80 weight %, and typically from about 20 to about 50 weight %, based on the total dry weight of the imageable layer. The weight ratio of the free radically polymerizable component to the total polymeric binders (described below) is generally from about 5:95 to about 95:5, and typically from about 10:90 to about 90:10, or even from about 30:70 to about 70:30.

The IR radiation-sensitive composition also includes an initiator composition that includes one or more initiators that are capable of generating free radicals sufficient to initiate polymerization of all the various free radically polymerizable components upon exposure of the composition to imaging radiation. The initiator composition is generally responsive to infrared imaging radiation corresponding to the spectral range of at least 700 nm and up to and including 1400 nm (typically from about 750 to about 1250 nm). Initiator compositions are used that are appropriate for the desired imaging wavelength(s).

Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged counterion. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

The iodonium cations can be paired with a suitable number of negatively-charged counterions such as halides, hexafluorophosphate, thiosulfate, hexafluoroantimonate, tetrafluoroborate, sulfonates, hydroxide, perchlorate, and others readily apparent to one skilled in the art.

Thus, the iodonium cations can be supplied as part of one or more iodonium salts, and as described below, the iodonium cations can be supplied as iodonium borates also containing suitable boron-containing anions. For example, the iodonium cations and the boron-containing anions can be supplied as part of salts that are combinations of Structures (IB) and (IBz) described below, or both the iodonium cations and boron-containing anions can be supplied from different sources. However, if they are supplied at least from the iodonium borate salts, since such salts generally supply about a 1:1 molar ratio of iodonium cations to boron-containing anions, additional iodonium cations must be supplied from other sources, for example, from iodonium salts described above.

For example, the imageable layer (and element) can comprise a mixture of iodonium cations, some of which are derived from an iodonium borate (described below) and others of which are derived from a non-boron-containing iodonium salt (described above). When both types of iodonium salts are present, the molar ratio of iodonium derived from the iodonium borate to the iodonium derived from the non-boron-containing iodonium salt can be up to 5:1 and typically up to 2.5:1.

One class of useful iodonium cations include diaryliodonium cations that are represented by the following Structure (IB):

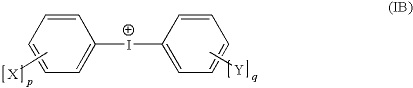

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylphentyl, all hexyl isomers, all octyl isomers, benzyl, 4-methoxybenzyl, p-methylbenzyl, all dodecyl isomers, all icosyl isomers, and substituted or unsubstituted mono-and poly-, branched and linear haloalkyls), substituted or unsubstituted alkyloxy having 1 to 20 carbon atoms (for example, substituted or unsubstituted methoxy, ethoxy, isopropoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds are preferred (that is, they have the same groups on both phenyl rings).

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5. Typically, both p and q are at least 1, or each of p and q is 1. Thus, it is understood that the carbon atoms in the phenyl rings that are not substituted by X or Y groups have a hydrogen atom at those ring positions.

Useful boron-containing anions are organic anions having four organic groups attached to the boron atom. Such organic anions can be aliphatic, aromatic, heterocyclic, or a combination of any of these. Generally, the organic groups are substituted or unsubstituted aliphatic or carbocyclic aromatic groups. For example, useful boron-containing anions can be represented by the following Structure (IBz):

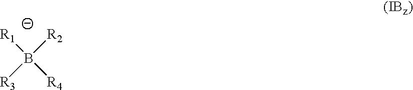

wherein R₁, R₂, R₃, and R₄ are independently substituted or unsubstituted alkyl groups having 1 to 12 carbon atoms (such as methyl, ethyl, n-propyl, isopropyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z⁻ can be a tetraphenyl borate wherein the phenyl groups are substituted or unsubstituted (for example, all are unsubstituted phenyl groups).

Some representative iodonium borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-4′-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]-borate, 4-methoxyphenyl-4′-cyclohexylphenyliodonium tetrakis(penta-fluorophenyl)borate, 4-methylphenyl-4′-dodecylphenyliodonium tetrakis(4-fluorophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

Such diaryliodonium borate compounds can be prepared, in general, by reacting an aryl iodide with a substituted or unsubstituted arene, followed by an ion exchange with a borate anion. Details of various preparatory methods are described in U.S. Pat. No. 6,306,555 (Schulz et al.), and references cited therein, and by Crivello, J. Polymer Sci., Part A: Polymer Chemistry, 37, 4241-4254 (1999), both of which are incorporated herein by reference.

The boron-containing anions can also be supplied as part of infrared radiation absorbing dyes (for example, cationic dyes) as described below. Such boron-containing anions generally are defined as described above with Structure (IBz).

The iodonium cations and boron-containing anions are generally present in the imageable layer in a combined amount of at least 1% and up to and including 15%, and typically at least 4 and up to and including about 10%, based on total dry weight of the imageable layer. The optimum amount of the various initiator components may differ for various compounds and the sensitivity of the radiation-sensitive composition that is desired and would be readily apparent to one skilled in the art.

The imageable layer may also include heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

Some useful initiator compositions include the following combinations:

iodonium cations supplied from non-boron containing iodonium salts only and boron-containing anions separately supplied from other salts including cationic infrared dyes,

iodonium cations supplied from both non-boron containing iodonium salts and iodonium borates and boron-containing anions from only the iodonium borates, or

iodonium cations supplied from both non-boron containing iodonium salts and iodonium borates and boron-containing anions from both iodonium borates and other sources (such as cationic IR dyes).

The IR radiation-sensitive composition sensitivity is provided by the presence of one or more infrared radiation absorbing compounds, chromophores, or sensitizers that absorb imaging radiation, or sensitize the composition to imaging infrared radiation having a λₘₐₓ of from about 700 nm and up to and including 1400 nm, and typically from about 700 to about 1200 nm.

Useful IR radiation absorbing chromophores include various IR-sensitive dyes (“IR dyes”). Examples of suitable IR dyes comprising the desired chromophore include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), U.S. Pat. No. 6,569,603 (noted above), U.S. Pat. No. 6,787,281 (Tao et al.), U.S. Pat. No. 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (noted above), U.S. Pat. No. 6,264,920 (Achilefu et al.), U.S. Pat. No. 6,153,356 (noted above), U.S. Pat. No. 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Some useful infrared radiation absorbing dyes have a tetraaryl pentadiene chromophore. Such chromophore generally includes a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Such IR-sensitive dyes can be represented by the following Structure DYE-II:

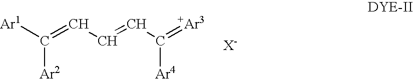

wherein Ar¹ through Ar⁴ are the same or different substituted or unsubstituted aryl groups having at least carbon atoms in the aromatic ring (such as phenyl, naphthyl, and anthryl, or other aromatic fused ring systems) wherein 1 to 3 of the aryl groups are substituted with the same or different tertiary amino group (such as in the 4-position of a phenyl group). Typically two of the aryl groups are substituted with the same or different tertiary amino group, and usually at different ends of the polymethine chain (that is, molecule). For example, Ar¹ or Ar² and Ar³ or Ar⁴ bear the tertiary amine groups. Representative amino groups include but are not limited to those substituted with substituted or unsubstituted alkyl groups having up to 10 carbon atoms or aryl groups such as dialkylamino groups (such as dimethylamino and diethylamino), diarylamino groups (such as diphenylamino), alkylarylamino groups (such as N-methylanilino), and heterocyclic groups such as pyrrolidino, morpholino, and piperidino groups. The tertiary amino group can form part of a fused ring such that one or more of Ar¹ through Ar⁴ can represent a julolidine group.

Besides the noted tertiary groups noted above, the aryl groups can be substituted with one or more substituted or unsubstituted alkyl groups having 1 to 10 carbon atoms, halo atoms (such as chloro or bromo), hydroxyl groups, thioether groups, and substituted or unsubstituted alkoxy groups having 1 to 10 carbon atoms. Substituents that contribute electron density to the conjugated system are useful. While they are not specifically shown in Structure (DYE-II), substituents or fused rings may also exist on (or as part of) the conjugated chain connecting the aryl groups.

In Structure (DYE-II), X⁻ is a suitable counterion that may be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, and halides.

Useful infrared radiation absorbing dyes can be obtained from a number of commercial sources including Showa Denko (Japan) or they can be prepared using known starting materials and procedures.

Still other useful infrared radiation absorbing compounds are copolymers can comprise covalently attached ammonium, sulfonium, phosphonium, or iodonium cations and infrared radiation absorbing cyanine anions that have two or four sulfonate or sulfate groups, or infrared radiation absorbing oxonol anions, as described for example in U.S. Pat. No. 7,049,046 (Tao et al.).

The infrared radiation absorbing compounds can be present in the IR-radiation sensitive composition (or imageable layer) in an amount generally of at least 1% and up to and including 30% and typically at least 3 and up to and including 20%, based on total solids in the composition, that also corresponds to the total dry weight of the imageable layer. The particular amount needed for this purpose would be readily apparent to one skilled in the art, depending upon the specific compound used to provide the desired chromophore.

The imageable layer includes a first polymeric binder and a second polymeric binder that are generally present within a weight ratio of the second polymeric binder to the first polymeric binder is from about 1:1 to about 1:20 (typically from about from about 1:1 to about 1:15, or from about 1: 1 to about 1:10. For example, the first polymeric binder is present in an amount of from about 10 to about 40 weight % (typically from about 15 to about 30 weight %), and the second polymeric binder is present in an amount of from about 0.5 to about 15 weight % (typically from about 1 to about 10 weight %), both based on the total dry weight of said imageable layer.

The first polymeric binder is present as discrete particles having an average particle size of from about 10 to about 500 nm, and typically from about 150 to about 450 nm, and that are generally distributed uniformly within that layer. The particulate polymeric binders exist at room temperature as discrete particles, for example in an aqueous dispersion. However, the particles can also be partially coalesced or deformed, for example at temperatures used for drying coated imageable layer formulations. Even in this environment, the particulate structure is not destroyed. Such polymeric binders generally have a molecular weight (Mₙ) of at least 30,000 and typically at least 50,000 to about 100,000, or from about 60,000 to about 80,000, as determined by refractive index.

Useful first polymeric binders generally include polymeric emulsions or dispersions of polymers having hydrophobic backbones to which are attached pendant poly(alkylene oxide) side chains, cyano side chains, or both, that are described for example in U.S. Pat. No. 6,582,882 (Pappas et al.), U.S. Pat. No. 6,899,994 (Huang et al.), U.S. Pat. No. 7,005,234 (Hoshi et al.), and U.S. Pat. No. 7,368,215 (Munnelly et al.) and US Patent Application Publication 2005/0003285 (Hayashi et al.) that are all incorporated herein by reference. More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, and various hydrophilic polymeric binders that may have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the first polymeric binders can also be particulate polymers that have a backbone comprising multiple (at least two) urethane moieties. Such polymeric binders generally have a molecular weight (Mₙ) of at least 2,000 and typically at least 100,000 to about 500,000, or from about 100,000 to about 300,000, as determined by dynamic light scattering.

Additional useful first polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (preferably from about 30 to about 500 nm and more preferably from about 30 to about 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents.

The second polymeric binders may be homogenous, that is, non-particulate or dissolved in the coating solvent, or they may exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in U.S. Pat. No. 7,175,949 (Tao et al.), and the polymers having pendant vinyl groups as described in U.S. Pat. No. 7,279,255 (Tao et al.), both incorporated herein by reference. Copolymers of polyethylene glycol methacrylate/acrylonitrile/styrene in particulate form, dissolved copolymers derived from carboxyphenyl methacrylamide/acrylonitrile/methacrylamide/N-phenyl maleimide, copolymers derived from polyethylene glycol methacrylate/acrylonitrile/vinyl carbazole/styrene/methacrylic acid, copolymers derived from N-phenyl maleimide/methacrylamide/methacrylic acid, copolymers derived from urethane-acrylic intermediate A (the reaction product of p-toluene sulfonyl isocyanate and hydroxyl ethyl methacrylate)/acrylonitrile/N-phenyl maleimide, and copolymers derived from N-methoxymethyl methacrylamide/methacrylic acid/acrylonitrile/n-phenylmaleimide are useful.

In many embodiments, the second polymeric binder can be represented by the following Structure (I):

-(A)ₓ-(B)_{y}—(C)_{z}— (I)

wherein A represents recurring units comprising pendant ethylenically unsaturated groups, B represents recurring units comprising pendant cyano groups, C represents recurring units different than A and B recurring units, x is from about 1 to about 70 mol %, y is from about 10 to about 80 mol %, and z is from about 20 to about 90 mol %.

In some embodiments, x is from about 5 to about 50 weight %, y is from about 10 to about 60 weight %, and z is from about 30 to about 80 weight %.

For example, in Structure (I), A can represent recurring units comprising pendant —C(═O)O—CH₂CH═CH₂ groups or have pendant allyl ester groups as described in U.S. Pat. No. 7,332,253 (Tao et al.) that is incorporated herein by reference. The pendant ethylenically unsaturated groups can be directly attached to the polymer backbone with a carbon-carbon direct bond, or through a linking group (“X”) that is not particularly limited. The reactive vinyl groups may be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.) that is incorporated herein by reference. Other useful polymeric binders have vinyl groups in pendant groups that are described, for example in EP 1,182,033A1 (Fujimaki et al.) and U.S. Pat. No. 4,874,686 (Urabe et al.), U.S. Pat. No. 7,729,255 (Tao et al.), U.S. Pat. No. 6,916,595 (Fujimaki et al.), and U.S. Pat. No. 7,041,416 (Wakata et al.) that are incorporated by reference, especially with respect to the general formulae (1) through (3) noted in EP 1,182,033A1.

For example, the reactive vinyl group can be represented by the structure: —X—CR¹═C(R²)R³ wherein X, R¹, R², and R³ are defined below.

For example, the reactive vinyl groups can be connected to the polymer backbone with a carbon-carbon direct bond or a linking group. For example, useful reactive vinyl groups are shown in Structure IIa and IIb below as Z′ groups. The X linking groups may be an oxy (—O—), thio (—S—), carbonyloxy [—C(O)O—], carbonamido [—C(O)NR′—], carbonyl [—C(O)—], amido (—NR′—), sulfonyl [—S(═O)₂O—], substituted or unsubstituted arylene group (such as a substituted or unsubstituted phenylene group), or a substituted or unsubstituted alkylene group (having 1 to 10 carbon atoms, such as a methylene group), or combinations of two or more of these groups. In particular, X may be an oxy, thio, —NR^{′}—, or substituted or unsubstituted arylene group having 6 to 10 carbon atoms in the ring (such as substituted or unsubstituted phenylene). R′ can be hydrogen, a substituted or unsubstituted alkyl group having 1 to 6 carbon atoms, or a substituted or unsubstituted aryl group having 6 or 10 carbon atoms in the ring. In many embodiments, X is a direct bond or a carbonyloxymethylene or a methyleneoxyphenylene group.

Z′ is represented by the following Structure (IIa) or (IIb):

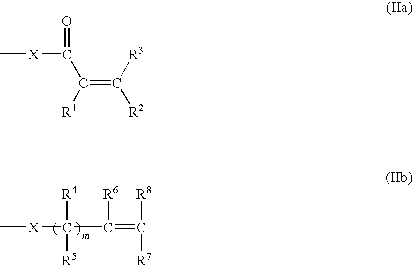

wherein X is defined as above.

R¹ to R⁸ independently represent monovalent organic groups of which there are hundreds of possibilities including but not limited to, hydrogen, substituted or unsubstituted alkyl groups having 1 to 10 carbon atoms, substituted or unsubstituted cycloalkyl groups having 5 to 10 carbon atoms in the unsaturated ring, substituted or unsubstituted aryl groups having 6 to 10 carbon atoms in the aromatic ring, substituted or unsubstituted heterocyclyl groups having 5 to 10 carbon, nitrogen, sulfur, or oxygen atoms in the aromatic or non-aromatic rings, cyano, halo, and vinyl groups.

When the pendant groups comprise the moiety represented by Structure IIb, R⁴ and R⁵ can be independently hydrogen or a substituted or unsubstituted alkyl group having 1 to 3 carbon atoms, and R⁶ to R⁸ can be independently hydrogen, or a halo group, substituted or unsubstituted alkyl group having 1 to 6 carbon atoms, or a substituted or unsubstituted phenyl group. For example, R⁶ to R⁸ can be independently hydrogen or a chloro, methyl, ethyl, or phenyl groups.

In Structure IIb, m is 0 or 1, and preferably it is 1.

For example, Z′ can be represented by the following Structure IIc:

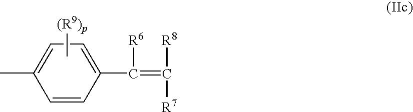

wherein R⁶ through R⁸ are as defined above, R⁹ is a substitutable group or atom that would be readily apparent to one skilled in the art, and p is an integer of 0 to 4. Most preferably, p is 0, and R⁶ through R⁸ are each hydrogen.

Some useful pendant reactive vinyl groups are alkenyl groups including but not limited to allyl esters, styryl, and (meth)acryloyl groups. For example, such groups can be provided by allyl (meth) acrylates, or by reacting a polymer precursor with an allyl halide, 4-vinylbenzyl chloride, or (meth)acryloyl chloride using conditions that would be apparent to a skilled worker in the art.

In Structure (I), B can represent recurring units comprising pendant cyano groups that are generally derived from one or more of (meth)acrylonitrile, cyanostyrenes, or cyano(meth)acrylates.

Moreover, the C recurring units can be derived from one or more (meth)acrylic acid esters, (meth)acrylamides, vinyl carbazole, styrene or styrene derivative, N-substituted maleimide, maleic anhydride, vinyl acetate, vinyl ketone, vinyl pyridine, N-vinyl pyrrolidone, 1-vinyl imidazole, (meth)acrylic acid, polysiloxanes, monomers having carboxy, phosphoric acid, or sulfonic acid groups, as well as salts thereof (such as carboxylates and sulfonates). Monomers from such recurring units can be derived include but are not limited to, carboxy-containing vinyl monomers, carboxylated styrenes, and sulfated styrenes. Ethylenically unsaturated polymerizable monomers that have carboxy groups, or that have reactive groups that can be converted to carboxy groups, or to which carboxy groups can be attached after polymerization, are particularly useful. Thus, the carboxy groups can be obtained from a number of synthetic methods. Useful monomers having pendant carboxylic acid groups include but are not limited to, (meth)acrylic acid, 4-carboxyphenyl (meth)acrylate, and 4-carboxystyrene.

Other useful C recurring units can be derived from one or more of vinyl carbazole or vinyl carbazole derivatives as described in U.S. Pat. No. 7,175,949 (Tao et al.), alkyl (meth)acrylates [such as methyl (meth)acrylates], (meth)acrylamides, N-phenyl maleimides, poly(alkylene glycol)methyl ether (meth)acrylates [such as poly(ethylene glycol)methyl ether (meth)acrylates], and styrene monomers such as substituted and unsubstituted styrene. Useful combinations of C recurring units include a combination of recurring units derived from two or more of a methyl (meth)acrylate, an N-vinyl carbazole, and a polyethylene glycol methyl ether (meth)acrylate. These are merely provided as examples and not intended to be limiting since a skilled artisan could use many other ethylenically unsaturated polymerizable monomers.

In some embodiments of this invention the imageable element comprises a weight ratio of the second polymeric binder to the first polymeric binder is from about 1:1 to about 1:20,

the first polymeric binder is present in an amount of from about 15 to about 30 weight %, and the second polymeric binder is present in an amount of from about 1 to about 10 weight %, both based on the total dry weight of the imageable layer, and

the second polymeric binder can be represented by Structure (I) noted above.

In still other embodiments, the imageable elements comprise a weight ratio of the second polymeric binder to the first polymeric binder is from about 1:1 to about 1:20,

the first polymeric binder is present in an amount of from about 10 to about 40 weight %, and the second polymeric binder is present in an amount of from about 0.5 to about 15 weight %, both based on the total dry weight of the imageable layer,

the second polymeric binder is represented by Structure (I) noted above.

Moreover, in any of these embodiments, the imageable elements can comprise a weight ratio of the second polymeric binder to the first polymeric binder is from about 1:1 to about 1:15,

the first polymeric binder is present in an amount of from about 15 to about 30 weight %, and the second polymeric binder is present in an amount of from about 1 to about 10 weight %, both based on the total dry weight of the imageable layer, and

in Structure (I), A represents recurring units comprises pendant —C(═O)O—CH₂CH═CH₂ groups, B represents recurring units comprising pendant cyano groups, C represents recurring units derived from one or more (meth)acrylic acid esters, (meth)acrylamides, vinyl carbazole, styrene or styrene derivative, N-substituted maleimide, maleic anhydride, vinyl acetate, vinyl ketone, vinyl pyridine, N-vinyl pyrrolidone, 1-vinyl imidazole, (meth)acrylic acid, or polysiloxanes, x is from about 5 to about 50 mol %, y is from about 10 to about 60 mol %, and z is from about 30 to about 80 mol %.

The various first and second polymeric binders can be obtained from a number of commercial sources, or prepared using known starting materials and reaction conditions.

The imageable layer can also include a spirolactone or spirolactam colorant precursor. Such compounds are generally colorless or weakly colored until the presence of an acid causes the ring to open providing a colored species, or more intensely colored species.

Examples of useful colorant precursors include but are not limited to, Crystal Violet Lactone, Malachite Green Lactone, 3-(N,N-diethylamino)-6-chloro-7-(β-ethoxyethylamino)fluoran, 3-(N,N,N-triethylamino)-6-methyl-7-anilinofluoran, 3-(N,N-diethylamino)-7-chloro-7-o-chlorofluoran, 2-(N-phenyl-N-methylamino)-6-(N-p-tolyl-N-ethyl)aminofluoran, 2-anilino-3-methyl-6-(N-ethyl-p-toluidino)fluoran, 3,6-dimethoxyfluoran, 3-(N,N-diethylamino)-5-methyl-7-(N,N-dibenzylamino)fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-chlorofluoran, 3-(N,N-diethylamino)-7-(4-chloroanilino)fluoran, 3-(N,N-diethylamio)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis((1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-azaphthalide, and 3-(4-diethylaminophenyl)-3-(1-ethyl-2-methylindol-3-yl)phthalide.

The colorant precursor described above can be present in an amount of at least 1 and up to 10 weight %, and typically from about 3 to about 6 weight %, based on the total dry imageable layer weight.

The radiation-sensitive composition (imageable layer) can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety. Such compounds and their use in imageable layers are described in more detail in U.S. Pat. No. 7,175,969 (Ray et al.) that is incorporated herein by reference.

The phosphate (meth)acrylate can be present in the radiation-sensitive composition in an amount of at least 0.5 and up to and including 20% and typically at least 0.9 and up to and including 10%, based on total dry composition weight.

The imageable layer can also include a “primary additive” that is a poly(alkylene glycol) or an ether or ester thereof that has a molecular weight of at least 200 and up to and including 4000. This primary additive can be present in an amount of at least 2 and up to and including 50 weight %, based on the total dry weight of the imageable layer. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are Sartomer SR9036 (ethoxylated (30) bisphenol A dimethacrylate), CD9038 (ethoxylated (30) bisphenol A diacrylate), SR399 (dipentaerythritol pentaacrylate), and Sartomer SR494 (ethoxylated (5) pentaerythritol tetraacrylate), and similar compounds all of which that can be obtained from Sartomer Company, Inc. In some embodiments, the primary additive may be “non-reactive” meaning that it does not contain polymerizable vinyl groups.

The imageable layer can also include a “secondary additive” that is a poly(vinyl alcohol), a poly(vinyl pyrrolidone), poly(vinyl imidazole), or polyester in an amount of up to and including 20 weight % based on the total dry weight of the imageable layer.

Additional additives to the imageable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.). Specific examples of phenolic compounds include but are not limited to, 2,4-dihydroxybenzophenone, 4,4′-isopropylidene-diephenol (Bisphenol A), p-t-butylphenol, 2,4,-dinitrophenol, 3,4-dichlorophenol, 4,4′-methylene-bis(2,6′-di-t-butylphenol), p-phenylphenol, 1,1-bis(4-hydroxyphenyl)cyclohexane, 1,1-bis(4-hydroxyphenyl)-2-ethylhexene, 2,2-bis(4-hydroxyphenyl)butane, 2,2′-methylenebis(4-t-butylphenol), 2,2′-methylenebis(α-phenyl-p-cresol)thiodiphenol, 4,4′-thiobis(6-t-butyl-m-cresol)sulfonyldiphenol, p-butylphenol-formalin condensate, and p-phenylphenol-formalin condensate. Examples of useful organic acids or salts thereof include but are not limited to, phthalic acid, phthalic anhydride, maleic acid, benzoic acid, gallic acid, o-toluic acid, p-toluic acid, salicylic, 3-t-butylsalicylic, 3,5-di-3-t-butylsalicylic acid, 5-α-methylbenzylsalicylic acid, 3,5-bis(α-methylbenzyl)salicylic acid, 3-t-octylsalicylic acid, and their zinc, lead, aluminum, magnesium, and nickel salts. Examples of the oxybenzoic acid esters include but are not limited to, ethyl p-oxybenzoate, butyl p-oxybenzoate, heptyl p-oxybenzoate, and benzyl p-oxybenzoate. Such color developers may be present in an amount of from about 0.5 to about 5 weight %, based on total imageable layer dry weight.

The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of a radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition.

The substrate generally has a hydrophilic surface, or at least a surface that is more hydrophilic than the applied radiation-sensitive composition on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both flat surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful substrate is an electrochemically grained and sulfuric acid anodized aluminum support that provides a hydrophilic surface for lithographic printing.

An interlayer may be formed by treatment of the aluminum support with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], poly(acrylic acid), or an acrylic acid copolymer to increase hydrophilicity. Still further, the aluminum support may be treated with a phosphate solution that may further contain an inorganic fluoride (PF). The aluminum support can be electrochemically-grained, phosphoric acid-anodized, and treated with poly(acrylic acid) using known procedures to improve surface hydrophilicity.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate may be coated with antistatic agents and/or slipping layers or a matte layer to improve handling and “feel” of the imageable element.

The substrate can also be a cylindrical surface having the radiation-sensitive composition applied thereon, and thus be an integral part of the printing press. The use of such imaging cylinders is described for example in U.S. Pat. No. 5,713,287 (Gelbart).

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer and an overcoat formulation is applied to that layer.

Illustrative of such manufacturing methods is mixing the radically polymerizable component, first and second polymeric binders, initiator composition, infrared radiation absorbing compound, and any other components of the radiation-sensitive composition in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0. 1 and up to and including 5 g/m² or at least 0.5 and up to and including 3.5 g/m².

Layers can also be present under the imageable layer to enhance developability or to act as a thermal insulating layer. The underlying layer should be soluble or at least dispersible in the developer and typically have a relatively low thermal conductivity coefficient.

The various layers may be applied by conventional extrusion coating methods from melt mixtures of the respective layer compositions. Typically such melt mixtures contain no volatile organic solvents.

Intermediate drying steps may be used between applications of the various layer formulations to remove solvent(s) before coating other formulations. Drying steps at conventional times and temperatures may also help in preventing the mixing of the various layers.

Once the various layers have been applied and dried on the substrate, the imageable element can be enclosed in water-impermeable material that substantially inhibits the transfer of moisture to and from the imageable element as described in U.S. Pat. No. 7,175,969 (noted above) that is incorporated herein by reference.

### Topcoat Layer Formulations

The imageable element includes what is conventionally known as an overcoat or topcoat layer (such as an oxygen impermeable topcoat) applied to and disposed over the imageable layer for example, as described in WO 99/06890 (Pappas et al.). Such topcoat layers comprise one or more water-soluble polymer binders chosen from such polymers as poly(vinyl alcohol)s, poly(vinyl pyrrolidone), poly(ethyleneimine), poly(vinyl imidazole), and copolymers of two or more of vinyl pyrrolidone, ethyleneimine, and vinyl imidazole, and generally have a dry coating weight of at least 0.1 and up to and including 2 g/m² (typically from about 0.1 to about 0.5 g/m²) in which the water-soluble polymer(s) comprise at least 50% and up to 98% of the dry weight of the topcoat layer. Topcoat layer polymer binders are also described in U.S. Pat. No. 3,458,311 (Alles), U.S. Pat. No. 4,072,527 (Fanni), and U.S. Pat. No. 4,072,528 (Bratt), and EP Publications 275,147A2 (Wade et al.), 403,096A2 (Ali), 354,475A2 (Zertani et al.), 465,034A2 (Ueda et al.), and 352,630A2 (Zertani et al.).

The topcoat layer can also include a composition that is capable of changing color upon exposure to imaging infrared radiation. This composition can comprise various component formulations. In one embodiment, it comprises: (1) an infrared absorbing compound, (2) a compound that, in the presence of this IR absorbing compound generates an acid in response to the imaging infrared radiation, and optionally (3) one or more compounds that provide a color change in the presence of an acid. Each of these components is defined below. In some embodiments, components (1) and (3) are the same, while in other embodiments, they are different. In the latter embodiments, component (3) can be a spirolactone or spirolactam colorant precursor. Such compounds are generally colorless or weakly colored until the presence of an acid causes the ring to open providing a colored species, or more intensely colored species.

For example, useful spirolactone and spirolactam colorant precursors include compounds represented by the Structure (CF) noted above.

More useful colorant precursors can be represented by the following Structure (CF-1):

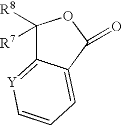

wherein Y is a nitrogen atom or methine group and R⁷ and R⁸ are as described above. Compounds wherein Y is a methine group are particularly useful.

Examples of useful colorant precursors in the topcoat include but are not limited to, Crystal Violet Lactone, Malachite Green Lactone, 3-(N,N-diethylamino)-6-chloro-7-(β-ethoxyethylamino)fluoran, 3-(N,N,N-triethylamino)-6-methyl-7-anilinofluoran, 3-(N,N-diethylamino)-7-chloro-7-o-chlorofluoran, 2-(N-phenyl-N-methylamino)-6-(N-p-tolyl-N-ethyl)aminofluoran, 2-anilino-3-methyl-6-(N-ethyl-p-toluidino)fluoran, 3,6-dimethoxyfluoran, 3-(N,N-diethylamino)-5-methyl-7-(N,N-dibenzylamino)fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-chlorofluoran, 3-(N,N-diethylamino)-7-(4-chloroanilino)fluoran, 3-(N,N-diethylamio)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis((1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-azaphthalide, and 3-(4-diethylaminophenyl)-3-(1-ethyl-2-methylindol-3-yl)phthalide.

Some specific useful colorant precursors are represented by the following structures:

| | |
|---|---|
| Red-40 | 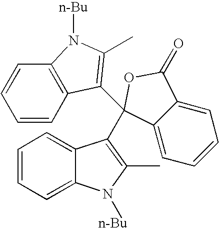 |
| GN-2 | 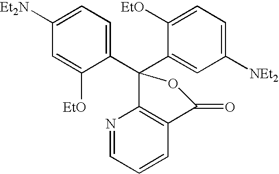 |
| ODB-2 | 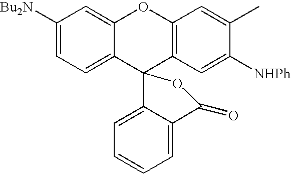 |
| Blue-63 | 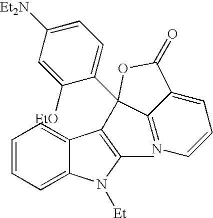 |
| Black-15 | 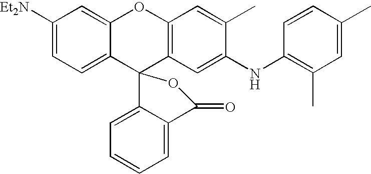 |
| ODB-4 | 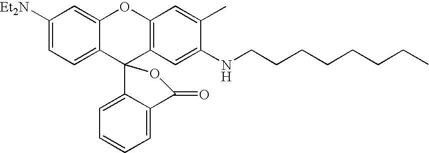 |

The colorant precursors can be present in the topcoat layer in an amount of at least 1 and up to 10%, and typically from about 3 to about 6%, based on the dry topcoat layer weight.

In many embodiments, component (1) is an infrared radiation absorbing cyanine dye (“IR dye”) that comprises a cyanine dye chromophore that is represented by the following Structure (CHROMOPHORE):

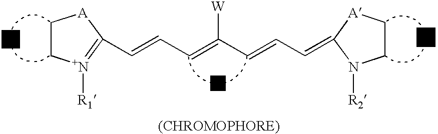

wherein W is —N(Q₁)(Q₂) or Cl. The Q₁ and Q₂ groups are independently substituted or unsubstituted aromatic carbocyclic groups, for example substituted or unsubstituted phenyl or naphthyl groups.

A and A′ are independently —S—, —O—, —NH—, —CH₂—, or —CR′R″— groups wherein R′ and R″ are independently substituted or unsubstituted alkyl groups having 1 to 8 carbon atoms (such as methyl, ethyl, isopropyl, t-butyl, n-hexyl, benzyl, and n-octyl groups). In addition, R′ and R″ together can form a substituted or unsubstituted cyclic group (either a substituted or unsubstituted carbocyclic or heterocyclic group having 5 or 6 atoms in the ring). For example, R′ and R″ can be independently substituted or unsubstituted alkyl groups having 1 to 4 carbon atoms. In some embodiments, A and A′ are both —C(CH₃)₂—.

Z represents the additional carbon atoms needed to provide a substituted or unsubstituted 5- to 7-membered carbocyclic ring, and typically to provide a 5-membered carbocyclic ring.

Z₁ and Z₂ are independently substituted or unsubstituted benzo or naphtho condensed rings. These rings can have one or more substituents such as substituted or unsubstituted alkyl, aryl, and alkoxy groups, or nitro, cyano, trifluoromethyl, acyl, halo, sulfono, carboxy, or sulfonate groups. In most embodiments, Z₁ and Z₂ are both unsubstituted benzo condensed rings.

R₁′ and R₂′ are independently substituted or unsubstituted alkyl groups having 1 to 12 carbon atoms (such as substituted or unsubstituted methyl, ethyl, isopropyl, t-butyl, benzyl, n-hexyl, decyl, and dodecyl groups), substituted or unsubstituted cycloalkyl groups having 5 to 10 carbon atoms in the ring (such as substituted or unsubstituted cyclopentyl and cyclohexyl groups), or substituted or unsubstituted aryl groups having 6 or 10 carbon atoms in the aromatic ring (such as phenyl, naphthyl, 3-methylphenyl, and 4-methoxyphenyl groups). More likely, R₁′ and R₂′ are independently substituted or unsubstituted alkyl groups having 1 to 4 carbon atoms.

This cyanine dye chromophore generally has one or more water-solubilizing groups such as carboxy (carboxylate), sulfo (sulfonate), and hydroxy groups. The carboxy and sulfo groups are most common. In some embodiments, at least three water-solubilizing groups are present. The water-solubilizing groups can be present on the heterocyclic rings or as part of a substituent anywhere in the molecule. For example, one or more of the Z₁, Z₂, R₁′, and R₂′ groups can comprise one or more carboxy or sulfo groups.

Thus, in many embodiments, W is —N(Q₁)(Q₂) wherein Q₁ and Q₂ are the same or different substituted or unsubstituted phenyl groups, A and A′ are independently —S—, —O—, or —CR′R″ groups wherein R′ and R″ are independently substituted or unsubstituted alkyl groups, Z₁ and Z₂ are each substituted or unsubstituted naphtho condensed rings, Z represents the atoms needed to complete a 5-membered carbocyclic ring, and R₁′ and R₂′ are independently substituted or unsubstituted alkyl groups having 1 to 4 carbon atoms, provided one or more of Z₁, Z₂, R₁′, and R₂′ comprise one or more carboxy or sulfo groups.

The cyanine dye chromophore described herein can be associated with any suitable cation.

The cyanine dyes can be generally present in the topcoat layer in an amount of from about 1 to about 12 weight %, typically from about 2 to about 8 weight %, based on total topcoat layer dry weight. These compounds can be readily prepared using known starting materials and procedures.

Compounds that generate an acid during exposure to infrared radiation (“acid generators”) can be ionic or non-ionic. Any compound that is soluble in the topcoat layer formulation and can generate an acid in those conditions is useful. Generally, they are materials that form Bronsted acid by thermally initiated decomposition.

Non-ionic acid generators include, for example, haloalkyl-substituted s-triazines that are s-triazines substituted with one to three CX₃ groups in which X is bromo or chloro. Examples of such compounds include but are not limited to, 2-phenyl-4,6-bis(trichloromethyl)-s-triazine, 2,4,6-tris(trichloromethyl)-s-triazine, 2-methyl-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, and 2-[4-(2-ethoxyethyl)-naphtho-1-yl]-4,6-bis-trichloromethyl-s-triazine. Examples of useful water-soluble haloalkyl-substituted s-triazines are described in U.S. Pat. No. 6,010,821 (Smith et al.) having a general structures shown in Columns 6 and 7. Another useful example is the water-soluble Triazine Initiator A described in EP 1,075,942 (Kawamura et al.) having the structure shown in paragraph [0098].

Ionic acid generators include, for example, onium salts in which the onium cation is iodonium, sulfonium, phosphonium, oxysulphoxonium, oxysulphonium, sulphoxonium, ammonium, diazonium, selenonium, or arsonium, and the anion is a chloride, bromide, or a non-nucleophilic anion such as tetra-fluoroborate, hexafluorophosphate, hexafluoroarsenate, hexafluoroantimonate, triflate, tetrakis(pentafluoro-phenyl)borate, pentafluoroethyl sulfonate, p-methyl-benzyl sulfonate, ethyl sulfonate, trifluoromethyl acetate, and pentafluoroethyl acetate. Typical onium salts include, for example, diphenyl iodonium chloride, diphenyl iodonium hexafluorophosphate, 4,4′-dicumyl iodonium chloride, 4,4′-dicumyl iodonium hexafluorophosphate, N-methoxy-α-picolinium-p-toluene sulfonate, 4-methoxybenzene-diazonium tetrafluoroborate, 4,4′-bis-dodecylphenyl iodonium-hexafluorophosphate, 2-cyanoethyl-triphenylphosphonium chloride, triphenyl sulfonium hexafluoroantimonate, triphenyl sulfonium tetrafluoroborate, 2-methoxy-4-aminophenyl diazonium hexafluorophosphate, phenoxyphenyl diazonium hexafluoroantimonate, and anilinophenyl diazonium hexafluoroantimonate.

The acid generating compound can be generally present in the topcoat layer formulation in an amount of from about 2 to about 25 weight % and typically from about 5 to about 22 weight %, based on total solids in that formulation.

Additional additives to the topcoat layer can include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.). Specific examples of phenolic compounds include but are not limited to, 2,4-dihydroxybenzophenone, 4,4′-isopropylidene-diephenol (Bisphenol A), p-t-butylphenol, 2,4,-dinitrophenol, 3,4-dichlorophenol, 4,4′-methylene-bis(2,6′-di-t-butylphenol), p-phenylphenol, 1,1-bis(4-hydroxyphenyl)cyclohexane, 1,1-bis(4-hydroxyphenyl)-2-ethylhexene, 2,2-bis(4-hydroxyphenyl)butane, 2,2′-methylenebis(4-t-butylphenol), 2,2′-methylenebis(α-phenyl-p-cresol)thiodiphenol, 4,4′-thiobis(6-t-butyl-m-cresol)sulfonyldiphenol, p-butylphenol-formalin condensate, and p-phenylphenol-formalin condensate. Examples of useful organic acids or salts thereof include but are not limited to, phthalic acid, phthalic anhydride, maleic acid, benzoic acid, gallic acid, o-toluic acid, p-toluic acid, salicylic, 3-t-butylsalicylic, 3,5-di-3-t-butylsalicylic acid, 5-α-methylbenzylsalicylic acid, 3,5-bis(α-methylbenzyl)salicylic acid, 3-t-octylsalicylic acid, and their zinc, lead, aluminum, magnesium, and nickel salts. Examples of the oxybenzoic acid esters include but are not limited to, ethyl p-oxybenzoate, butyl p-oxybenzoate, heptyl p-oxybenzoate, and benzyl p-oxybenzoate. Such color developers may be present in an amount of from about 0.5 to about 5 weight %, based on total topcoat layer dry weight.

### Imaging Conditions

During use, the imageable element is exposed to a suitable source of imaging or exposing near-infrared or infrared radiation, depending upon the radiation absorbing compound present in the radiation-sensitive composition, at a wavelength of from about 700 to about 1500 nm. For example, imaging can be carried out using imaging or exposing radiation, such as from an infrared laser at a wavelength of at least 700 nm and up to and including about 1400 nm and typically at least 750 nm and up to and including 1250 nm. Imaging can be carried out using imaging radiation at multiple wavelengths at the same time if desired.

The laser used to expose the imageable element is usually a diode laser, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Creo Trendsetter® platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

For example, in some embodiments, the imageable element contains an IR-sensitive dye and the imagewise exposing step A is carried out using radiation having a maximum wavelength of from about 700 to about 1200 nm at an energy level of from about 20 to about 500 mJ/cm².

While laser imaging is desired in the practice of this invention, imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

### Development and Printing

With or without a post-exposure baking step after imaging and before development, the imaged elements can be developed “on-press” as described in more detail below. In most embodiments, a post-exposure baking step is omitted. On-press development avoids the use of alkaline developing solutions typically used in conventional processing apparatus. The imaged element is mounted on press wherein the unexposed regions in the imageable layer are removed by a suitable fountain solution, lithographic printing ink, or a combination of both, when the initial printed impressions are made. Typical ingredients of aqueous fountain solutions include pH buffers, desensitizing agents, surfactants and wetting agents, humectants, low boiling solvents, biocides, antifoaming agents, and sequestering agents. A representative example of a fountain solution is Varn Litho Etch 142W+Varn PAR (alcohol sub) (available from Varn International, Addison, Ill.).

The fountain solution is taken up by the non-imaged regions, that is, the surface of the hydrophilic substrate revealed by the imaging and development steps, and ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of the invention but are by no means intended to limit the invention in any manner.

### EXAMPLES

The components and materials used in the examples and analytical methods used in evaluation were as follows. Unless otherwise indicated, the components can be obtained from Aldrich Chemical Company (Milwaukee, Wis.):

Aqua-image cleaner/preserver was obtained from Eastman Kodak Company (Rochester, N.Y.).

Elvacite® 4206 is a 10% (weight) solution of a highly branched poly(methyl methacrylate) in MEK that was obtained from Lucite International, Inc. (Cordova, Tenn.).

FluorN™2900 is a fluorosurfactant obtained from Cytonix Corporation (Beltsville, Md.).

IB05 represents bis(4-t-butylphenyl) iodonium tetraphenylborate.

IPA represents iso-propyl alcohol.

Masurf® FS-1520 is a fluoroaliphatic betaine fluorosurfactant that was obtained from Mason Chemical Company (Arlington Heights, Ill.).

MEK represents methyl ethyl ketone.

Naxan-ABL is a sodium alkylnaphthalene sulfonate that was obtained from Nease Corporation (Cincinnati, Ohio).

NK Ester A-DPH is a dipentaerythritol hexaacrylate that was obtained from Kowa American (New York, N.Y.).

Phosmer PE is an ethylene glycol methacrylate phosphate with 4-5 ethoxy groups that was obtained from Uni-Chemical Co. Ltd. (Japan).

Polymer A is a 10/70/20 weight percent copolymer emulsion/dispersion of polyethylene glycol methyl ether methacrylate/acrylonitrile/styrene (25%).

Polymer B is a 12.3/9.6/48.3/8.1/21.7 mole percent copolymer of methyl methacrylate/acrylonitrile/vinyl carbazole/methacrylic acid/allyl methacrylate.

Polymer C is a 25/30/25/10/10 weight percent copolymer of methyl methacrylate/acrylonitrile/vinyl carbazole/methacrylic acid/vinyl benzyl methacrylate.

Prisco LPC is a liquid plate cleaner that was obtained from Prisco (Newark, N.J.).

Prisco Fountain Concentrate 3451 is a fountain solution that was obtained from Prisco (Newark, N.J.).

Prisco Alkaless 6000 is an alcohol replacement that was obtained from Prisco (Newark, N.J.).

PVA-403 is a PVOH (Polyvinyl Alcohol) plastic material that was obtained from Kuraray America, Inc. (Houston, Tex.).

S0930 is an IR dye that was obtained from FEW Chemicals GmbH (Germany):

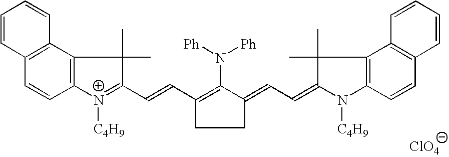

SR399 is dipentaerythritol pentaacrylate that was obtained from Sartomer Company, Inc.

SR415 is ethoxylated (20) trimethylolpropane triacrylate that was obtained from Sartomer Company, Inc.

UV plate cleaner was obtained from Allied Pressroom Chemistry, Inc. (Hollywood, Fla.).

Varn Litho Etch 142W fountain solution was obtained from Varn International (Addison, Ill.).

Varn-120 plate cleaner was obtained from Varn International.

Varn PAR alcohol replacement was obtained from Varn International.

The “RH Test” was a high humidity accelerated aging test carried out at 38° C. and a relative humidity of 85% for 5 days.

### Invention Example 1

### Negative-Working Imageable Element and Imaging Method—Two Layer using a Combination of Polymer A and Polymer B

An imageable layer formulation was prepared by dissolving or dispersing 10.2 g of Polymer A, 0.7 g of Polymer B, 3.1 g of SR399, 3.1 g of NK ester A-DPH, 0.3 g of Phosmer PE, 0.5 g of IB-05, 0.2 g of S0930, and 1.2 g of FluorN™ 2900 (5% in PGME) in 21.0 g of MEK and 89.8 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. An imaged fresh element was developed by 50 impressions under the application of the both fountain solution and ink and another 200 impressions were printed and showed strong images of both solid and highlights using exposure energies as low as 57 mJ/cm².

### Invention Example 2

### Negative-Working Imageable Element and Imaging Method—Two Layer using a Combination of Polymer A and Polymer B

An imageable layer formulation was prepared by dissolving or dispersing 8.8 g of Polymer A, 0.7 g of Polymer B, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 90.8 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. An imaged fresh element was developed in 17 impressions under the application of the both fountain solution and ink and another 200 impressions were printed and showed strong images of both solid and highlights using exposure energies as low as 70 mJ/cm².

### Invention Example 3

### Negative-Working Imageable Element and Imaging Method—Two Layer using a Combination of Polymer A and Polymer B

An imageable layer formulation was prepared by dissolving or dispersing 7.3 g of Polymer A, 1.0 g of Polymer B, 3.4 g of SR399, 3.4 g of NK ester A-DPH, 0.3 g of Phosmer PE, 0.5 g of IB-05, 0.2 g of S0930, 0.3g of Naxan-ABL (50% in H₂O), and 1.2 g of FluorN™ 2900 (5% in PGME) in 20.6 g of MEK and 91.9 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. An imaged fresh element was developed in 21 impressions under the application of the both fountain solution and ink and another 200 impressions were printed and showed strong images of both solid and highlights using exposure energies as low as 47 mJ/cm².

### Invention Example 4

### Negative-Working Imageable Element and Imaging Method—Two Layer using a Combination of Polymer A and Polymer C

An imageable layer formulation was prepared by dissolving or dispersing 10.8 g of Polymer A, 0.2 g of Polymer C, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 89.4 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. An imaged fresh element was developed in 1 impression under the application of the both fountain solution and ink and another 200 impressions were printed and showed strong images of both solid and highlights using exposure energies as low as 50 mJ/cm².

Another imaged element was tested on a Komori sheet-fed press using a wear ink containing 1.5% calcium carbonate and fountain solution containing Prisco Fountain Concentrate 3451 at 5 oz/gal (39 ml/liter) and Prisco Alkaless 6000 alcohol replacement at 4 oz/gal (31.2 ml/liter). It was developed on press using a combination of both fount and ink during a press startup procedure of 12 revolutions with only the water form engaged followed by 4 revolutions with both the water and ink forms engaged. The printing plate did not show any solid wear and highlight fading after 30,000 impressions at an exposure energy of 120 mJ/cm².

### Invention Example 5

### Negative-Working Imageable Element and Imaging Method—Two Layer using a Combination of Polymer A and Polymer C

An imageable layer formulation was prepared by dissolving or dispersing 10.2 g of Polymer A, 0.3 g of Polymer C, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 89.8 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. An imaged fresh element was developed in 1 impression under the application of the both fountain solution and ink and another 200 impressions were printed and showed strong images of both solid and highlights using exposure energies as low as 50 mJ/cm².

Another imaged element was tested on a Komori sheet-fed press using a wear ink containing 1.5% calcium carbonate and fountain solution containing Prisco Fountain Concentrate 3451 at 5 oz/gal (39 ml/liter) and Prisco Alkaless 6000 alcohol replacement at 4 oz/gal (31.2 ml/liter). It was developed on press using a combination of both fount and ink during a press startup procedure of 12 revolutions with only the water form engaged followed by 4 revolutions with both the water and ink forms engaged. The printing plate did not show any solid wear and highlight fading after 30,000 impressions at an exposure energy of 120 mJ/cm².

### Invention Example 6

### Negative-Working Imageable Element and Imaging Method—Two Layer using a Combination of Polymer A and Polymer C

An imageable layer formulation was prepared by dissolving or dispersing 9.7 g of Polymer A, 0.5 g of Polymer C, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 90.2 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. An imaged fresh element was developed in 16 impressions under the application of the both fountain solution and ink and another 200 impressions were printed and showed strong images of both solid and highlights using exposure energies as low as 43 mJ/cm².

Another imaged element was tested on a Komori sheet-fed press using a wear ink containing 1.5% calcium carbonate and fountain solution containing Prisco Fountain Concentrate 3451 at 5 oz/gal (39 ml/liter) and Prisco Alkaless 6000 alcohol replacement at 4 oz/gal (31.2 ml/liter). It was developed on press using a combination of both fount and ink during a press startup procedure of 12 revolutions with only the water form engaged followed by 4 revolutions with both the water and ink forms engaged. The printing plate did not show any solid wear and highlight fading after 35,000 impressions at an exposure energy of 120 mJ/cm².

### Invention Example 7

### Negative-Working Imageable Element and Imaging Method—Two Layer using a Combination of Polymer A and Polymer C

An imageable layer formulation was prepared by dissolving or dispersing 8.8 g of Polymer A, 0.7 g of Polymer C, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 90.8 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz/gal (23.4 ml/liter) and PAR alcohol replacement at 3 oz/gal (23.4 ml/liter) and van Son Rubber Base black ink VS151. An imaged fresh element was developed in 21 impressions under the application of the both fountain solution and ink and another 200 impressions were printed and showed strong images of both solid and highlights using exposure energies as low as 40 mJ/cm².

### Comparative Example 1

### Without Topcoat, Compare to Invention Example 5

An imageable layer formulation was prepared by dissolving or dispersing 10.2 g of Polymer A, 0.3 g of Polymer C, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 89.8 g of methanol. This formulation was applied to an electrochemically grained and sulfuric acid anodized aluminum substrate that had been post-treated with phosphate fluoride to provide a dry coating weight of about 0.9 g/m². The formulation was applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz/gal (23.4 ml/liter) and PAR alcohol replacement at 3 oz/gal (23.4 ml/liter) and van Son Rubber Base black ink VS151. An imaged fresh element was developed in 9 impressions under the application of the both fountain solution and ink and another 200 impressions were printed and showed strong images of both solid and highlights using exposure energies as low as 40 mJ/cm². After the “RH” test identified above the imaged element was observed not to develop after 200 sheets.

### Comparative Example 2

### Compare to Invention Example 5, Two Layer using Polymer A

An imageable layer formulation was prepared by dissolving or dispersing 1 1.6 g of Polymer A, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 89.8 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz/gal (23.4 ml/liter) and PAR alcohol replacement at 3 oz/gal (23.4 ml/liter) and van Son Rubber Base black ink VS151. An imaged fresh element was developed between 25-50 impressions under the application of the both fountain solution and ink and another 200 impressions were printed and showed strong images of both solid and highlights using exposure energies as low as 40 mJ/cm².

### Comparative Example 3

### Compare to Invention Example 5, Two Layer using Polymer C

An imageable layer formulation was prepared by dissolving or dispersing 11.6 g of Polymer C, 3.5 g of SR399, 3.5 g of NK ester A-DPH, 0.3 g of Phosmer PE, 0.5 g of IB-05, 0.2 g of S0930, and 1.2 g of FluorN™ 2900 (5% in PGME) in 20.5 g of MEK and 89.8 g of methanol. This formulation was applied to an electrochemically grained and sulfuric acid anodized aluminum substrate that had been post-treated with phosphate fluoride to provide a dry coating weight of about 0.9 g/m². On the resulting imageable layer, a topcoat formulation comprising 5.4 g of PVA-403, 12.0 g of IPA, 279.8 g of water, and 2.7 g of Masurf® FS-1520 was applied to provide a dry coating weight of about 0.4 g/m². Both formulations were applied using a slot coater pilot line and then dried for 90 seconds at a temperature setting of 175° F. (79° C.). The resulting imageable element was placed on a Kodak® Trendsetter 3244× image setter and exposed using an 830 nm IR laser.

The imaged element was mounted on an AB Dick duplicator press charged with fountain solution containing Varn Litho Etch 142W at 3 oz/gal (23.4 ml/liter) and PAR alcohol replacement at 3 oz/gal (23.4 ml/liter) and van Son Rubber Base black ink VS151. An imaged fresh element was not developed by 200 impressions.

The invention has been described in detail with particular reference to certain preferred embodiments thereof, but it will be understood that variations and modifications can be effected within the spirit and scope of the invention.

1. A negative-working, on-press developable imageable element comprising a substrate having thereon an imageable layer and a topcoat as the outermost layer, said imageable layer comprising:
a free radically polymerizable component,
an initiator composition capable of generating radicals sufficient to initiate polymerization of said free radically polymerizable component upon exposure to imaging radiation,
an infrared radiation absorbing compound,
a first polymeric binder that is present as discrete particles distributed throughout said imageable layer, and
a second polymeric binder that comprises a hydrophobic backbone and pendant ethylenically unsaturated groups.

2. The element of claim 1 wherein the weight ratio of said second polymeric binder to said first polymeric binder is from about 1:1 to about 1:20.

3. The element of claim 1 wherein said topcoat is hydrophilic and said second polymeric binder is non-particulate.

4. The element of claim 1 wherein said first polymeric binder is present in an amount of from about 10 to about 40 weight %, and said second polymeric binder is present in an amount of from about 0.5 to about 15 weight %, both based on the total dry weight of said imageable layer.

5. The element of claim 1 wherein said second polymeric binder can be represented by the following Structure (I):
-(A)ₓ-(B)_{y}—(C)_{z}— (I)
wherein A represents recurring units comprising pendant ethylenically unsaturated groups, B represents recurring units comprising pendant cyano groups, C represents recurring units different than A and B recurring units, x is from about 1 to about 70 mol %, y is from about 10 to about 80 mol %, and z is from about 20 to about 90 mol %.

6. The element of claim 1 wherein said substrate is a sulfuric acid-anodized aluminum-containing substrate.

7. The element of claim 1 wherein said free radically polymerizable component comprises an ethylenically unsaturated free-radical polymerizable monomer or oligomer, or a free-radical crosslinkable polymer.

8. The element of claim 1 wherein said infrared radiation absorbing compound is an infrared radiation absorbing dye.

9. The element of claim 1 wherein said initiator composition comprises an onium salt.

10. The element of claim 9 wherein said onium salt is an iodonium borate comprising a diaryliodonium borate compound represented by the following Structure (II): 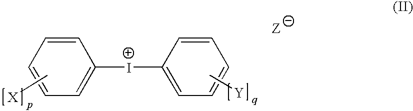
wherein X and Y are independently halo, alkyl, alkyloxy, or cycloalkyl groups or two or more adjacent X or Y groups can be combined to form a fused ring with the respective phenyl rings, p and q are independently 0 or integers of 1 to 5, and
Z⁻ is an organic anion represented by the following Structure (III): 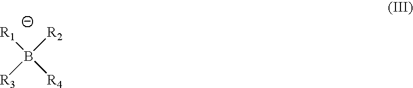
wherein R₁, R₂, R₃, and R₄ are independently alkyl, aryl, alkenyl, alkynyl, cycloalkyl, or heterocyclyl groups, or two or more of R₁, R₂, R₃, and R₄ can be joined together to form a heterocyclic ring with the boron atom.

11. The element of claim 1 wherein said topcoat comprises a poly(vinyl alcohol).

12. The element of claim 1 comprising a weight ratio of said second polymeric binder to said first polymeric binder is from about 1:1 to about 1:20,
said first polymeric binder is present in an amount of from about 15 to about 30 weight %, and said second polymeric binder is present in an amount of from about 1 to about 10 weight %, both based on the total dry weight of said imageable layer,
said second polymeric binder can be represented by the following Structure (I):
-(A)ₓ-(B)_{y}—(C)_{z}— (I)
wherein A represents recurring units comprising pendant ethylenically unsaturated groups, B represents recurring units comprising pendant cyano groups, C represents recurring units different than A and B recurring units, x is from about 5 to about 50 mol %, y is from about 10 to about 60 mol %, and z is from about 30 to about 80 mol %.

13. A method of making an imaged element comprising:
A) imagewise exposing the negative-working imageable element of claim 1 to form exposed and non-exposed regions,
B) with or without a preheat step, developing said imagewise exposed element to remove predominantly only said non-exposed regions.

14. The method of claim 13 wherein said development is carried out on-press using a fountain solution, lithographic printing ink, or both.

15. The method of claim 13 wherein said imageable element contains an IR-sensitive dye and said imagewise exposing step A is carried out using radiation having a maximum wavelength of from about 700 to about 1200 nm at an energy level of from about 20 to about 500 mJ/cm².

16. The method of claim 13 wherein said imageable element comprises a sulfuric acid-anodized aluminum-containing substrate.

17. The method of claim 13 wherein said imageable element comprises a weight ratio of said second polymeric binder to said first polymeric binder is from about 1:1 to about 1:20,
said first polymeric binder is present in an amount of from about 10 to about 40 weight %, and said second polymeric binder is present in an amount of from about 0.5 to about 15 weight %, both based on the total dry weight of said imageable layer,
said second polymeric binder can be represented by the following Structure (I):
-(A)ₓ-(B)_{y}—(C)_{z}— (I)
wherein A represents recurring units comprising pendant ethylenically unsaturated groups, B represents recurring units comprising pendant cyano groups, C represents recurring units different than A and B recurring units, x is from about 1 to about 70 mol %, y is from about 10 to about 80 mol %, and z is from about 20 to about 90 mol %.

18. The method of claim 17 wherein said imageable element comprises a weight ratio of said second polymeric binder to said first polymeric binder is from about 1:1 to about 1:15,
said first polymeric binder is present in an amount of from about 15 to about 30 weight %, and said second polymeric binder is present in an amount of from about 1 to about 10 weight %, both based on the total dry weight of said imageable layer, and
in Structure (I), A represents recurring units comprises pendant —C(═O)O—CH₂CH═CH₂ groups, B represents recurring units comprising pendant cyano groups, C represents recurring units derived from one or more (meth)acrylic acid esters, (meth)acrylamides, vinyl carbazole, styrene or styrene derivative, N-substituted maleimide, maleic anhydride, vinyl acetate, vinyl ketone, vinyl pyridine, N-vinyl pyrrolidone, 1-vinyl imidazole, (meth)acrylic acid, or polysiloxanes, x is from about 5 to about 50 mol %, y is from about 10 to about 60 mol %, and z is from about 30 to about 80 mol %.

19. An imaged lithographic printing plate obtained from the method of claim 13.
